(19) United States
(12) Patent Application Publication
(10) Pub. No.: US 2010/0295088 A1
(43) Pub. Date: Nov. 25, 2010

(54) TEXTURED-SURFACE LIGHT EMITTING DIODE AND METHOD OF MANUFACTURE

(75) Inventors: MARK P. D'EVELYN, Goleta, CA (US); RAJAT SHARMA, Goleta, CA (US); ERIC M. HALL, Goleta, CA (US); DANIEL F. FEEZELL, Goleta, CA (US); MATHEW C. SCHMIDT, Goleta, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignees: SORAA, INC., Goleta, CA (US); KAAI, INC., Goleta, CA (US)

(21) Appl. No.: 12/569,841

(22) Filed: Sep. 29, 2009

Related U.S. Application Data
(60) Provisional application No. 61/102,347, filed on Oct. 2, 2008.

(51) Int. Cl. H01L 33/62

(52) U.S. Cl. 257/99; 438/26; 257/E33.066; 257/E33.056

(57) ABSTRACT

A high efficiency textured-surface light emitting diode comprises a flip-chipped stack of AlₓIn_{y}Ga_{1-x-y}N layers, where 0≦x, y, x+y≦1. Each layer has a high crystalline quality, with a dislocation density below about 10⁵ cm⁻². The backside of the stack, exposed by removal of the original substrate, has a textured surface for improved light extraction.

### CROSS-REFERENCES TO RELATED APPLICATIONS

This application claims priority to U.S. Provisional Patent Application No. 61/102,347 filed Oct. 2, 2008, commonly assigned, and of which is incorporated in its entirety by reference herein for all purposes.

### STATEMENT AS TO RIGHTS TO INVENTIONS MADE UNDER FEDERALLY SPONSORED RESEARCH AND DEVELOPMENT

Not Applicable

### REFERENCE TO A “SEQUENCE LISTING,” A TABLE, OR A COMPUTER PROGRAM LISTING APPENDIX SUBMITTED ON A COMPACT DISK

Not Applicable

### BACKGROUND OF THE INVENTION

The present invention relates generally to optical techniques. More specifically, embodiments of the invention include techniques for fabricating a light emitting diode device using bulk gallium nitride containing materials. Merely by way of example, the invention can be applied to applications such as optoelectronic devices, and the like.

Much progress has been made during the past decade and a half in the performance of gallium nitride (GaN) based light emitting diodes (LEDs). Devices with a luminous efficiency higher than 100 lumens per watt have been demonstrated in the laboratory, and commercial devices have an efficiency that is already considerably superior to that of incandescent lamps and competitive with that of fluorescent lamps. Further improvements in efficiency are desired in order to reduce operating costs, reduce electricity consumption, and decrease emissions of carbon dioxide and other greenhouse gases produced in generating the energy used for lighting applications.

The efficiency of LEDs is limited in part by the internal quantum efficiency and by the light extraction efficiency. The internal quantum efficiency can be improved by the use of bulk gallium nitride substrates, with low concentrations of threading dislocations, and by the use of nonpolar and semipolar crystallographic orientations, which reduce or eliminate the presence of deleterious polarization electric fields within the device.

The light extraction efficiency can be improved by the use of surface texturing, particularly in combination with thinning or removal of the substrate. For example, Fujii et al. [Applied Physics Letters 84, 855 (2004)] discussed flip-chip bonding of a conventional GaN-on-sapphire LED, laser-liftoff of the sapphire substrate, and photoelectrochemical etching of the freshly exposed n-type layer to provide a textured surface with improved light extraction capability. However, this approach suffers from several limitations. The use of a sapphire or other non-GaN substrate, while providing a means for removal of the substrate, does not achieve low dislocation densities in the active layer, which may negatively impact the internal quantum efficiency. Additionally, photoelectrical etching provides a convenient means for texturing of the (0 0 0 −1) N-face GaN surface, which is limiting.

U.S. Pat. No. 7,053,413 (the '413 patent), hereby incorporated by reference in its entirety, discloses fabrication of a homoepitaxial LED on a bulk GaN substrate with a dislocation density below 10⁴ cm⁻², followed by removal of a portion of the substrate. However, the '413 patent is generally limited to removal using lapping, polishing, chemical etching, plasma etching, and ion beam etching for removal of the substrate portion. These methods do not appear to provide a natural endpoint, and it is therefore extremely difficult to remove all but a few- or sub-micron-thick layer of uniform thickness, and are slow and expensive to perform.

What is needed is a manufacturable technique for fabricating an LED with improved light extraction capability and, simultaneously, an improved defect density and improved crystallographic quality device structure with desired internal quantum efficiency.

### BRIEF SUMMARY OF THE INVENTION

According to the present invention, optical techniques are provided. More specifically, embodiments of the invention include techniques for fabricating a light emitting diode device using bulk gallium nitride containing materials. Merely by way of example, the invention can be applied to applications such as optoelectronic devices, and the like.

In a specific embodiment, the present invention provides a method of making a light emitting diode. The method includes providing a high quality nitride crystal comprising a base nitride crystal and an overlying release layer. In a specific embodiment, the high quality nitride crystal comprises a gallium species and a nitrogen species and having a surface dislocation density below 10⁵ cm⁻². The method forms an n-type semiconductor layer comprising a gallium species and nitrogen species overlying the release layer and a semiconductor active layer comprising a gallium species and a nitrogen species. In a specific embodiment, the semiconductor active layer is characterized by a peak light emission wavelength, and a p-type semiconductor layer comprising a gallium species and a nitrogen species overlying the high quality nitride crystal to form a sandwiched structure. In a specific embodiment, the method forms a reflective metallic contact overlying the p-type semiconductor layer. In a specific embodiment, the present method also separates the base nitride crystal from the sandwiched structure to expose a portion of the n-type layer. The method also processes, using at least etching, at least half of the exposed portion of the n-type layer to form one or more pyramidal structures, with side angles of between about 10 degrees and about 90 degrees with respect to the exposed portion of the n-type layer. The one or more pyramidal structures has a characteristic length scale between about 10 nm and about 1000 nm.

In an alternative specific embodiment, the present invention provides a light emitting diode device. The device includes a semiconductor active layer comprising a gallium species and a nitrogen species. The semiconductor active layer is characterized by a peak emission wavelength. The device also has a semiconductor n-type layer comprising a gallium species and a nitrogen species underlying the semiconductor active layer. The device has a semiconductor p-type layer comprising a gallium species and a nitrogen species overlying the semiconductor active layer and an electrical contact coupled to one or more portions of the semiconductor n-type layer. The device has a reflective electrical contact coupled to at least one of the semiconductor p-type layer or the semiconductor n-type layer and an active layer surface dislocation density below about 10⁵ cm⁻² characterizing the active layer. The device has an n-type layer surface dislocation density below about 10⁵ cm⁻² characterizing the n-type layer and a p-type layer surface dislocation density below about 10⁵ cm⁻² characterizing the p-type layer. In a specific embodiment, the device has one or more pyramidal structures texturing at least half of a surface region of at least one of the n-type layer or p-type layer. The one or more pyramidal structures has a plurality of pyramidal angles of between about 10 degrees and about 90 degrees with respect to the surface region and the one or more pyramidal structures has a characteristic length scale between about 10 nm and about 1000 nm.

The present invention achieves these benefits and others in the context of known process technology. However, a further understanding of the nature and advantages of the present invention may be realized by reference to the latter portions of the specification and attached drawings.

### BRIEF DESCRIPTION OF THE DRAWINGS

FIGS. 1 through 4 are simplified side-view diagrams of alternative LED device structures according to embodiments of the present invention;

FIG. 5 is a simplified diagram of a lift off method according to an embodiment of the present invention; and

FIGS. 6 through 13 are simplified side-view diagrams illustrating various methods of manufacturing LED device structures according to embodiments of the present invention.

### DETAILED DESCRIPTION OF THE INVENTION

According to the present invention, optical techniques are provided. More specifically, embodiments of the invention include techniques for fabricating a light emitting diode device using bulk gallium nitride containing materials. Merely by way of example, the invention can be applied to applications such as optoelectronic devices, and the like. For clarity, and consistent with standard usage in the art, unless otherwise specified, the term “wavelength” as used herein refers to the wavelength of radiation propagating in air and may be donoted by the symbol λ.

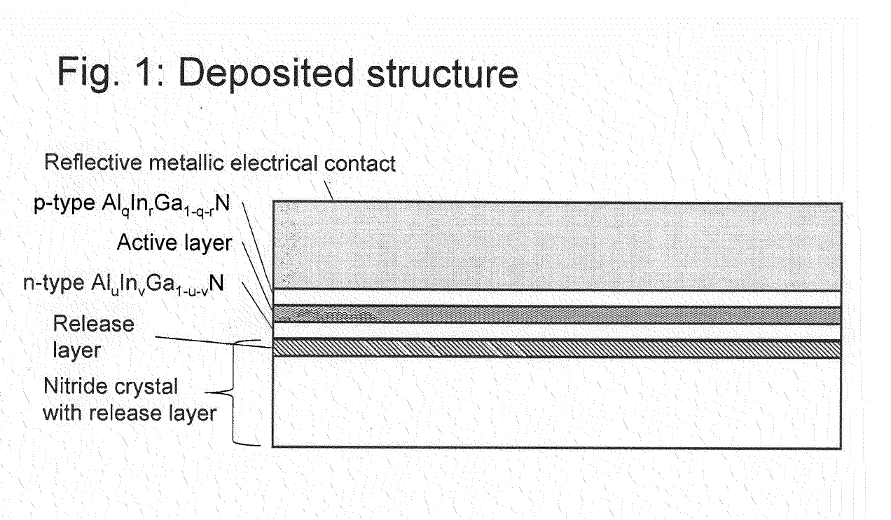

Referring to FIG. 1, the starting point for the present invention is a substrate consisting essentially of a high quality nitride crystal with a release layer, as disclosed in U.S. Patent application 61/091,591, entitled, “Nitride crystal with release layer, method of making, and method of use,” which is hereby incorporated by reference in its entirety. The nitride crystal comprises nitrogen and has a surface dislocation density below 10⁵ cm⁻². The nitride crystal or wafer may comprise AlₓIn_{y}Ga_{1-x-y}N, where 0≦x, y, x+y≦1. In one specific embodiment, the nitride crystal comprises GaN. In a preferred embodiment, the nitride crystal is substantially free of low-angle grain boundaries, or tilt boundaries, over a length scale of at least 3 millimeters. The nitride crystal has a release layer with an optical absorption coefficient greater than 1000 cm⁻¹ at least one wavelength where the base crystal underlying the release layer is substantially transparent, with an optical absorption coefficient less than 50 cm⁻¹, and may further comprise a high quality epitaxial layer, which also has a surface dislocation density below 10⁵ cm⁻². The release layer may be etched under conditions where the nitride base crystal and the high quality epitaxial layer are not.

The substrate may have a large-surface orientation within ten degrees, within five degrees, within two degrees, within one degree, within 0.5 degree, or within 0.2 degree of (0 0 0 1), (0 0 0 −1), {1 −1 0 0}, {1 1 −2 0}, {1 −1 0±1}, {1 −1 0±2}, {1 −1 0±3}, {2 0 −2±1}, or {1 1 −2±2}. In one specific embodiment, the substrate has a semipolar large-surface orientation, which may be designated by (hkil) Bravais-Miller indices, where i=−(h+k), l is nonzero and at least one of h and k are nonzero. The substrate may have a dislocation density below 10⁴ cm⁻², below 10³ cm⁻², or below 10² cm⁻². The nitride base crystal or wafer may have an optical absorption coefficient below 100 cm⁻¹, below 50 cm⁻¹ or below 5 cm⁻¹ at wavelengths between about 465 nm and about 700 nm. The nitride base crystal may have an optical absorption coefficient below 100 cm⁻¹, below 50 cm⁻¹ or below 5 cm⁻¹ at wavelengths between about 700 nm and about 3077 nm and at wavelengths between about 3333 nm and about 6667 nm.

In a preferred embodiment, the release layer comprises heavily cobalt-doped GaN, has a high crystal quality, and is substantially black, with an optical absorption coefficient greater than 1000 cm⁻¹ or greater than 5000 cm⁻¹ across the visible spectrum, including the range between about 465 nm and about 700 nm. The release layer is between about 0.05 micron and about 50 microns thick and has a temperature stability approximately the same as the underlying base crystal and exhibits minimal strain with respect to the underlying base crystal.

The nitride crystal may further comprise a high quality epitaxial layer on top of the release layer. In some embodiments the high quality layer is doped, for example, with Si or O to form n-type material, with a dopant concentration between about 10¹⁷ cm⁻³ and 10²⁰ cm⁻³.

If it is not already present in the surface region of the substrate, an n-type AlᵤInᵥGa₁₋ᵤ₋ᵥN layer, where 0≦u, v, u+v≦1, is deposited on the substrate. The carrier concentration may lie in the range between about 10¹⁷ cm⁻³ and 10²⁰ cm⁻³. The deposition may be performed using metalorganic chemical vapor deposition (MOCVD) or molecular beam epitaxy (MBE).

For example, the substrate is placed on a susceptor in an MOCVD reactor. After closing, evacuating, and back-filling the reactor to atmospheric pressure, the susceptor is heated to a temperature between about 1000 and about 1200 degrees Celsius in the presence of a nitrogen-containing gas. In one specific embodiment, the susceptor is heated to approximately 1185 degrees Celsius under flowing ammonia. A flow of a gallium-containing metalorganic precursor, such as trimethylgallium (TMG) or triethylgallium (TEG) is initiated, in a carrier gas, at a total rate between approximately 5 and 50 standard cubic centimeters per minute (sccm). The carrier gas may comprise hydrogen, helium, nitrogen, or argon. The ratio of the flow rate of the group V precursor (ammonia) to that of the group III precursor (trimethylgallium, triethylgallium, trimethylindium, trimethylaluminum) during growth is between about 2000 and about 12000. A flow of disilane in a carrier gas, with a flow rate of between about 0.1 and 10 sccm, is initiated.

In some embodiments, an Al-rich AlGaN layer is incorporated into the structure as an etch-stop layer. The etch-stop layer may be 25-100 nm thick and may have an Al/Ga ratio between about 0.1 and 0.2, and may be deposited below or within the n-type AlᵤInᵥGa₁₋ᵤ₋ᵥN layer.

Following deposition of the n-type AlᵤInᵥGa₁₋ᵤ₋ᵥN layer for a predetermined period of time, so as to achieve a predetermined thickness, an active layer is deposited. The active layer may comprise a single quantum well or a multiple quantum well, with 2-10 quantum wells. The quantum wells may comprise InGaN wells and GaN barrier layers. In other embodiments, the well layers and barrier layers comprise Al_{w}InₓGa_{1-w-x}N and Al_{y}In_{z}Ga_{1-y-z}N, respectively, where 0≦w, x, y, z, w+x, y+z≦1, where w<u, y and/or x>v, z so that the bandgap of the well layer(s) is less than that of the barrier layer(s) and the n-type layer. The well layers and barrier layers may each have a thickness between about 1 nm and about 20 nm. In another embodiment, the active layer comprises a double heterostructure, with an InGaN or Al_{w}InₓGa_{1-w-x}N layer about 20 nm to about 500 nm thick surrounded by GaN or Al_{y}In_{z}Ga_{1-y-z}N layers, where w<u, y and/or x>v, z. The composition and structure of the active layer are chosen to provide light emission at a preselected wavelength. The active layer may be left undoped (or unintentionally doped) or may be doped n-type or p-type.

In some embodiments, an electron blocking layer is deposited next. The electron-blocking layer may comprise AlₛInₜGa₁₋ₛ₋ₜN, where 0≦s, t, s+t≦1, with a higher bandgap than the active layer, and may be doped p-type. In one specific embodiment, the electron blocking layer comprises AlGaN. In another embodiment, the electron blocking layer comprises an AlGaN/GaN multiquantum barrier (MQB), comprising alternating layers of AlGaN and GaN, each with a thickness between about 0.2 nm and about 5 nm.

Next, a p-type doped Al_{q}InᵣGa_{1-q-r}N, where 0≦q, r, q+r≦1, layer is deposited above the active layer. The p-type layer may be doped with Mg, to a level between about 10¹⁷ cm⁻³ and 10²¹ cm⁻³, and may have a thickness between about 5 nm and about 500 nm. The outermost 1-30 nm of the p-type layer may be doped more heavily than the rest of the layer, so as to enable an improved electrical contact.

In a specific embodiment, a tunnel junction and another n-type layer are deposited on top of the p-type layer.

The semiconductor layers have the same crystallographic orientation, to within about two degrees, as the substrate, have a very high crystalline quality, comprise nitrogen, and have a surface dislocation density below 10⁵ cm². The semiconductor layers may have a dislocation density below 10⁴ cm⁻², below 10³ cm⁻², or below 10² cm⁻². In some embodiments, the semiconductor layers are substantially transparent, with an optical absorption coefficient below 100 cm⁻¹, below 50 cm⁻¹ or below 5 cm⁻¹ at wavelengths between about 700 nm and about 3077 nm and at wavelengths between about 3333 nm and about 6667 nm. In a preferred embodiment, the semiconductor layers are substantially free of low-angle grain boundaries, or tilt boundaries, over a length scale of at least 3 millimeters.

In a specific embodiment, the semiconductor layers have an orientation within five degrees of m-plane and the FWHM of the 1-100 x-ray rocking curve of the top surface is below 300 arc sec, below 100 arc sec, or below 50 arc sec. In another specific embodiment, the semiconductor layers have an orientation within five degrees of a-plane and the FWHM of the 11-20 x-ray rocking curve of the top surface is below 300 arc sec, below 100 arc sec, or below 50 arc sec. In yet another specific embodiment, the semiconductor layers have an orientation within five degrees of a semi-polar orientation selected from {1 −1 0±1}, {1 −1 0±2}, {1 −1 0±3}, {2 0 −2±1}, or {1 1 −2±2} and the FWHM of the lowest-order semipolar symmetric x-ray rocking curve of the top surface is below 300 arc sec, below 100 arc sec, or below 50 arc sec. In another specific embodiment, the semiconductor layers have an orientation within five degrees of (0001) c-plane and the FWHM of the 0002 x-ray rocking curve of the top surface is below 300 arc sec, below 100 arc sec, or below 50 arc sec. In still another specific embodiment, the semiconductor layers have an orientation within five degrees of (000-1) c-plane and the FWHM of the 000-2 x-ray rocking curve of the top surface is below 300 arc sec, below 100 arc sec, or below 50 arc sec.

In a preferred embodiment, the total thickness of the semiconductor layers, as measured between the removal layer and the outermost surface of the p-type layer or of the tunnel junction plus second n-type layer, if the latter are present, is between approximately 0.2 micron and 25 microns. In a specific embodiment, the total thickness of the semiconductor layers, as measured between the removal layer and the outermost surface of the p-type layer, is between approximately 0.5 micron and 5 microns.

A reflective electrical contact, with a reflectivity greater than about 70%, is then deposited on the p-type semiconductor layer or on the second n-type layer above a tunnel junction, if it is present. In another embodiment, the reflective electrical contact is placed on the n-type side of the device structure. In a preferred embodiment, the reflectivity of the reflective electrical contact is greater than 80% or greater than 90%. The reflective electrical contact may comprise at least one of silver, gold, aluminum, nickel, platinum, rhodium, palladium, chromium, or the like. The reflective electrical contact may be deposited by thermal evaporation, electron beam evaporation, sputtering, or another suitable technique. In a preferred embodiment, the reflective electrical contact serves as the p-type electrode for the textured-surface LED. In another embodiment, the reflective electrical contact serves as an n-type electrode for the textured-surface LED.

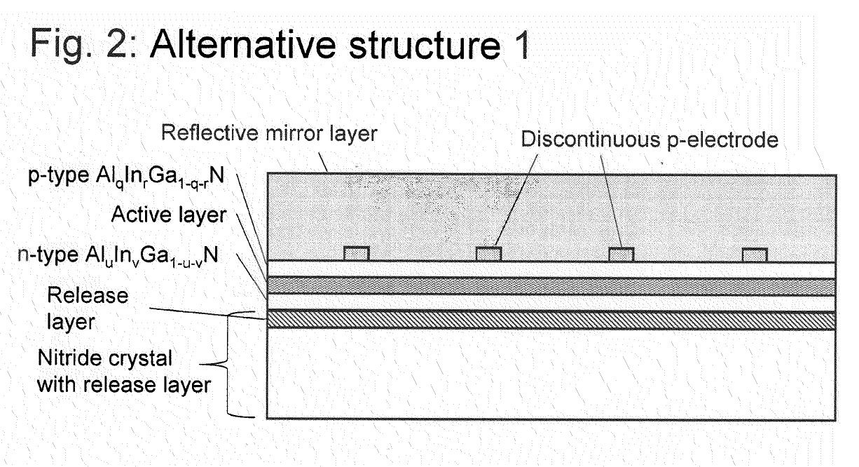

In some embodiments, as shown in FIG. 2, the reflective electrical contact comprises a two-component mirror/p-electrode including a discontinuous p-electrode and a reflective mirror layer. The discontinuous p-electrode is optimized as an electrical contact and can be made, for example, of a nickel/gold or a platinum/gold stack where the nickel or platinum is about 20 to 200 nm thick and the gold is about 100 nm to 1 micron thick. In one suitable embodiment, the discontinuous p-electrode is a gridded electrode having grid openings of between about 1 micron and 0.1 cm on a side. The reflective mirror layer may comprise at least one of silver, gold, aluminum, platinum, rhodium, palladium, chromium, or the like, and is deposited over the p-type later and over the gridded p-electrode. Preferably, the mirror layer is deposited after any annealing processing of the discontinuous p-electrode to reduce interdiffusion. Optionally, a diffusion barrier layer such as nickel, rhodium, platinum, palladium, iridium, ruthenium, rhenium, tungsten, molybdenum, niobium, tantalum, or MCₓN_{y}O_{z} (where M includes a metallic element such as aluminum, boron, silicon, titanium, vanadium, chromium, yttrium, zirconium, lanthanum, or a rare earth metal, and x, y, z are each between 0 and 3) is disposed between the discontinuous p-electrode and the mirror layer. Rather than a grid configuration, the discontinuous p-electrode can be arranged as an array of dots, rectangles, circles, or the like. The separation between the p-electrode array elements is preferably between about 1 micron and 0.1 cm. The use of a reflective metal p-electrode or combination of reflective mirror layer and discontinuous electrode enables fabrication of large area microcavity light emitting diodes without necessitating lateral carrier transport through p-doped layers over large distances.

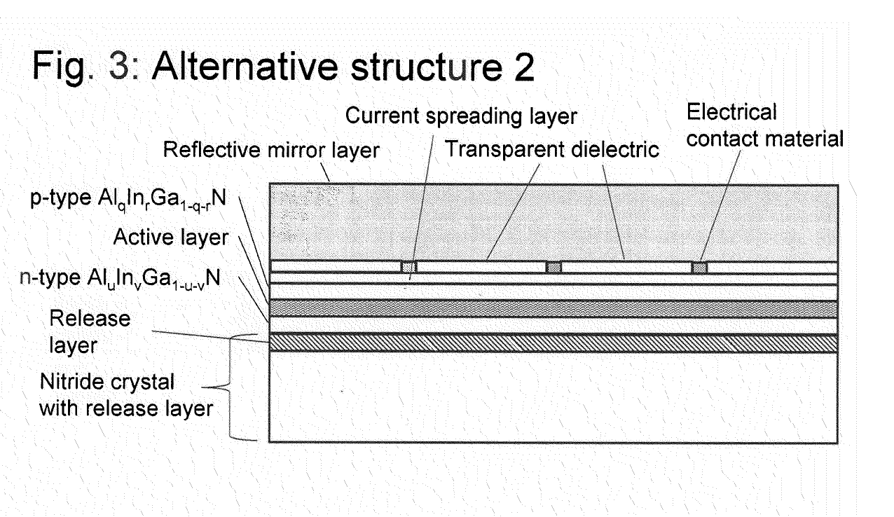

In another set of embodiments, as illustrated in FIG. 3, the reflective electrical contact further comprises a semi-transparent current-spreading layer. The current-spreading layer may comprise at least one of nickel oxide (NiO), nickel oxide/gold (NiO/Au), NiO/Ag, indium tin oxide (ITO), p-type zinc oxide (ZnO), ruthenium oxide (RuO₂), or the like. The current-spreading layer facilitates electrical contact to the p-type GaN layer, for example, ohmic or quasi-ohmic behavior. To minimize light absorption in the semi-transparent current-spreading layer, this layer has a thickness which is preferably between about 1 nm and about 10 nm, with more than 70% light transmission. The reflective electrical contact may further comprise a transparent dielectric disposed on a portion of the semitransparent current-spreading layer. The transparent dielectric may comprise at least one of TiO₂, Ta₂O₅, ZrO₂, SiO₂, SiOₓ, SiNₓ, Si₃N₄, or SiOₓN_{y}. The transparent dielectric may be a quarter-wave thick, that is, have a thickness approximately equal to one-quarter of the peak emission wavelength divided by the refractive index. The transparent dielectric includes open areas in which an electrical contact material is disposed. The electrical contact material may comprise at least one of nickel (Ni), nickel oxide (NiO), titanium-tungsten/gold (Ti—W/Au). In a preferred embodiment, the electrical contact material does not extend over the transparent dielectric. A reflective mirror layer is disposed over the transparent dielectric and the electrical contact material and electrically interconnects the electrical contact material in the various grid openings. The reflective mirror layer also cooperates with the transparent dielectric to define a reflector for reflecting light generated in the active layer. Further variations of the reflective metallic contact are described in U.S. Pat. No. 7,119,372, which is hereby incorporated by reference in its entirety.

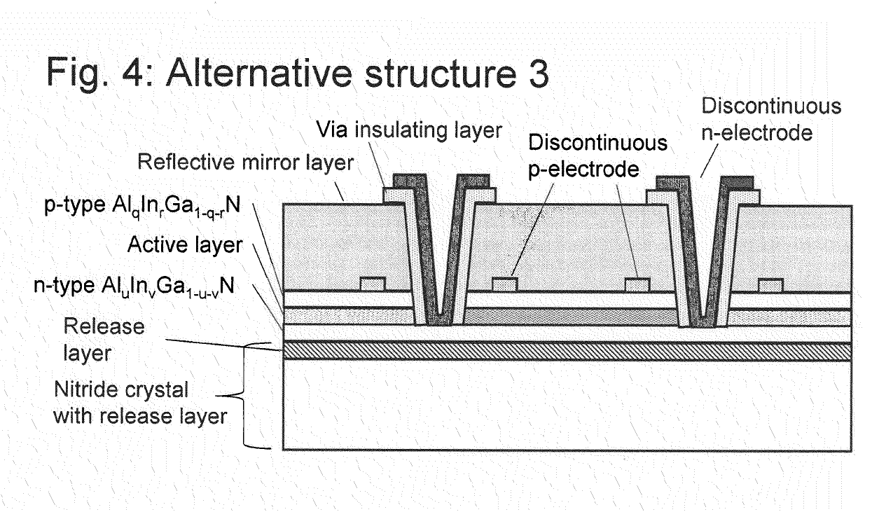

In some embodiments, n-type contacts are placed on the same side of the device as the p-type contacts, as shown in FIG. 4. Vias are etched through the reflective electrical contact, the p-type layer and the active layer, to expose portions of the n-type layer. The walls of the vias are coated with a via insulating layer comprising a dielectric, such as at least one of SiO₂, SiOₓ, SiNₓ, Si₃N₄, or SiOₓN_{y}. The inner portions of the via insulating layer are then coated with a suitable metal to form a discontinuous n-type electrode. The composition of the n-type electrode may comprise at least one of Ti, Al, and Au, or a stack thereof.

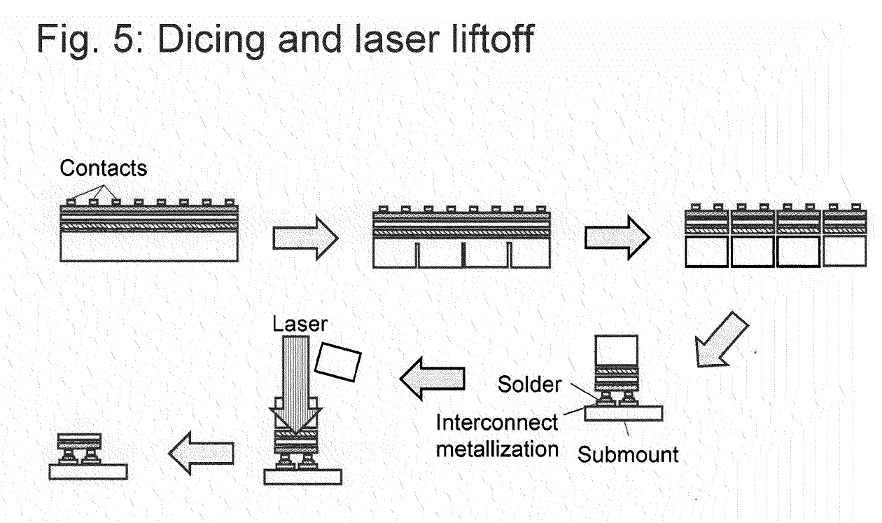

The wafer, comprising the LED structure, may be separated into one or more discrete dies, as shown in FIG. 5. For example, the backside of the wafer may be mechanically or laser scribed and then cleaved to form one or more discrete dies. At least one die may be flip-chip bonded to a submount or to a metal substrate. The submount may comprise silicon, aluminum nitride, CuW, aluminum oxide, another ceramic, or the like. In some embodiments, the p-type electrical contact is attached to interconnect metallization on the submount or to the metal substrate by means of a solder joint. The solder joint may comprise at least one of In, PbSn, AuSn, and SnAuCu. The solder joint may be formed by gold plating the back of the reflective electrical contact, evaporating Sn onto the gold layer, flipping the die and placing it in contact with a Au-coated submount, and heating to a temperature of about 280 degrees Celsius. Pressure may be placed on the joint to assist in forming a robust bond. The die may be additionally bonded to the submount or metal substrate by at least one of epoxy and wax.

The semiconductor structure, comprising the n-type layer, the active layer, the p-type layer, and the reflective electrical contact, may be separated from the nitride base crystal, or at least from the portion of the nitride base crystal still attached to the die. The removal may be effected by laser liftoff. The release layer may be illuminated by laser radiation at a wavelength at which it has an optical absorption coefficient greater than 1000 cm⁻¹ and the base crystal is substantially transparent, with an optical absorption coefficient less than 50 cm⁻¹. In one set of embodiments, the removal layer is illuminated by laser radiation through the nitride base crystal. Separation may be performed at a temperature above the melting point of the metal produced by decomposition, e.g., above about 30 degrees Celsius in the case of gallium metal.

After separation of the high quality epitaxial layer from the nitride base crystal, any residual gallium, indium, or other metal or nitride on the newly exposed back surface of the high quality epitaxial layer may be removed by treatment with at least one of hydrogen peroxide, an alkali hydroxide, tetramethylammonium hydroxide, an ammonium salt of a rare-earth nitrate, perchloric acid, sulfuric acid, nitric acid, acetic acid, hydrochloric acid, and hydrofluoric acid. The back side of the high quality epitaxial layer may be further cleaned or damage removed by dry-etching in at least one of Ar, Cl₂, and BCl₃, by techniques such as chemically-assisted ion beam etching (CAIBE), inductively-coupled plasma (ICP) etching, or reactive ion etching (RIE). The back side of the high quality epitaxial layer may be further treated by chemical mechanical polishing.

In some embodiments, traces of the release layer may remain after laser liftoff or etching from the edges of the release layer. Residual release layer material may be removed by chemical etching or by photoelectrochemical etching, illuminating the back side of the high quality epitaxial layer with radiation at a wavelength at which the release layer has an optical absorption coefficient greater than 1000 cm⁻¹ and the high quality epitaxial layer is substantially transparent, with an optical absorption coefficient less than 50 cm⁻¹.

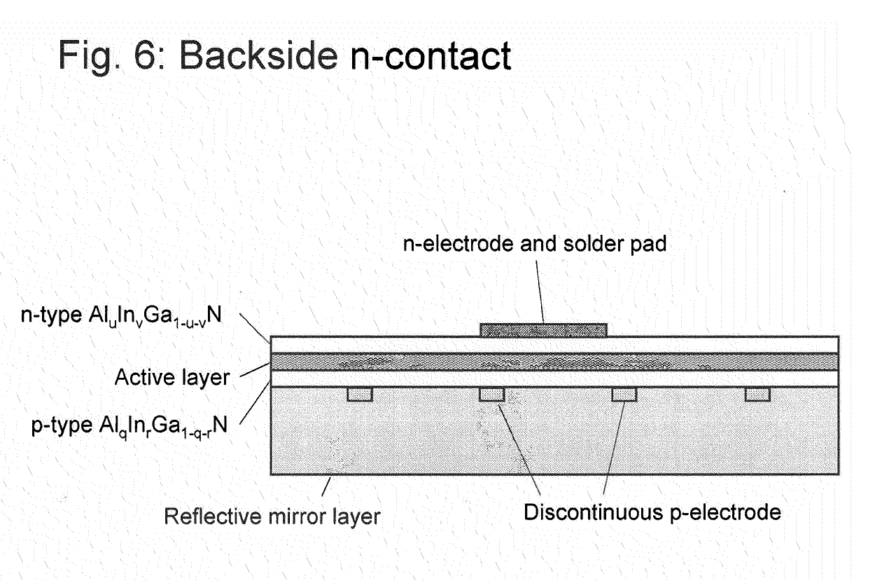

In some embodiments, an n-type contact is deposited on the freshly-exposed backside of the n-type layer, as shown in FIG. 6. The composition of the n-type electrode may comprise at least one of Ti, Al, and Au, or a stack thereof. The n-contact may comprise a solder pad and may further comprise a current-spreading pattern, such as lines emanating from the solder pad, a grid pattern, a transparent conductive oxide such as indium tin oxide, or the like.

In one specific embodiment, the LED has a (0 0 0 1) orientation and the freshly-exposed backside of the n-type layer has a (0 0 0 −1) crystallographic orientation. A textured structure may be applied to at least half of the surface of the n-type layer. Texturing may be provided to at least half of the freshly-exposed n-type layer by photoelectrochemical etching. For example, at least half of the exposed surface of the n-type layer may be immersed in an electrolyte solution. The solution may comprise KOH, at a concentration between about 0.001 and about 10 moles per liter. The solution may further comprise an oxidizing agent, such as K₂S₂O₈, at a concentration between about 0.001 and about 10 moles per liter. In other embodiments, the solution may comprise an acid, such as at least one of HCl, H₂SO₄, HNO₃, HF, H₃PO₄, CH₃COOH, and HClO₄, at a concentration between about 0.001 and about 10 moles per liter. An electrical bias may be applied to the n-type layer with respect to a Pt counterelectrode, at a voltage between about 0.001 and 4 volts. At least half of the exposed surface of the n-type layer may be illuminated by ultraviolet light. The ultraviolet light may have a wavelength less than about 365 nm and be emitted from a Xe or Hg—Xe lamp at a power between about 100 watts and about 5000 watts. A pyramidal-shaped texture, with a pyramidal angle expressed with respect to the large-area surface of approximately 62 degrees, substantially terminated by {1 −10 −1} facets, may be formed, with a characteristic length scale between about 10 nm and about 1000 nm, or between about 120 nm and about 250 nm. The characteristic length scale refers to the average lateral separation between adjacent pyramidal peaks or valleys. Without wishing to be bound by theory, the inventors believe that light extraction is facilitated by a surface texture structure with a characteristic length scale approximately equal to the emission wavelength within the semiconductor layers, or within a factor of 0.5 to 2 times the emission wavelength within the semiconductor layers, and by a pyramidal angle between 10 degrees and about 90 degrees.

As used herein, the term “pyramidal” is meant to also encompass surface textures that might variously be described as conical or tapered, or as pyramidal, conical, or tapered with geometric defects present. Rounded features, as might be called microlenses, are also understood to be pyramidal features. The pyramidal structures may be regularly shaped, irregularly shaped, or disfigured. The pyramidal structures may comprise one or more annular regions.

As used herein, the term “textured” refers to a surface that is textured, roughened with sharp or rounded features, elevated or raised features, grooved, or the like. The textured structure may be characterized by a plurality of localized pyramidal angles of between about 10 degrees and about 90 degrees with respect to the surface region and the one or more textured structures may have a characteristic lateral length scale between about 10 nm and about 1000 nm.

In other embodiments, for example, where the freshly-exposed backside of the n-type layer has a {1 −1 0 −1}, {1 1 −2 −2}, {1 −1 0 0}, or (0 0 0 1) crystallographic orientation, photoelectrochemical etching may not produce a favorable surface texture. In these embodiments, the appropriate surface texture may be formed by patterned anisotropic etching.

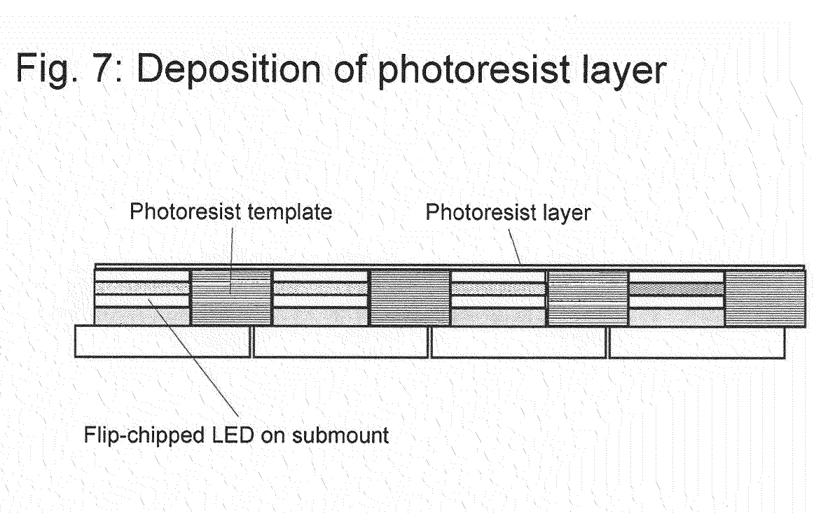

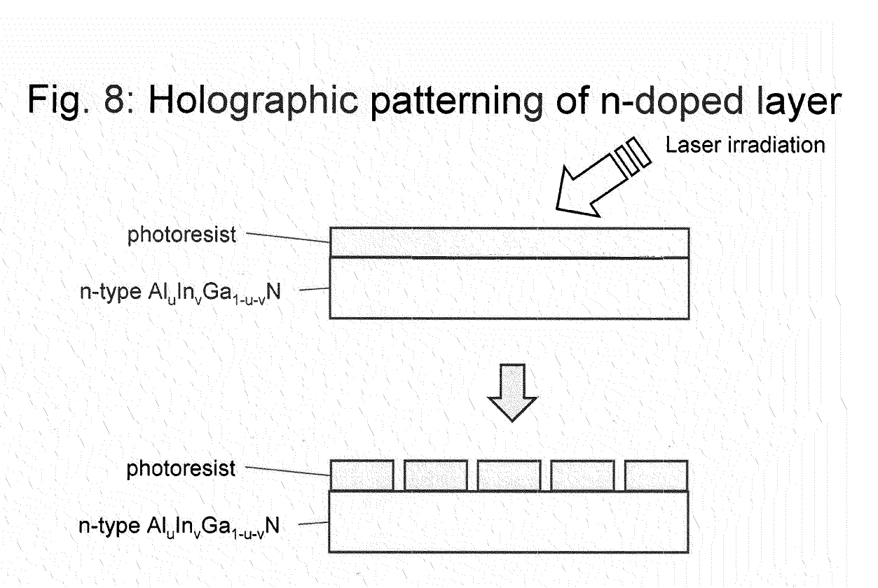

In one set of embodiments, illustrated in FIGS. 7 and 8, a mask with a predetermined characteristic length scale may be formed by holographic photolithography. In order to spread a photoresist cost-effectively over the separated dies, the flip-chipped LEDs may be placed in a submount carrier and a photoresist template may be placed over the submounts, as shown in FIG. 7. The photoresist template may have cutouts in the shape of the dies, with a gap of less than 1 mm, less than 0.2 mm, less than 0.1 mm, or less than 0.05 mm, between the edges of the cutouts and the dies. The flip-chipped dies may have a net height that is constant to within 50 microns, 20 microns, 10 microns, 5 microns, 2 microns, or 1 micron, so that the height difference between the photoresist template and an individual die is less than about 50 microns, less than about 20 microns, less than about 10 microns, less than about 5 microns, less than about 2 microns, or less than about 1 micron. A photoresist may then be dispensed onto the surface formed by the tops of the dies and the photoresist template and applied by spin-coating. Suitable examples of the photoresist are Shipley SPR-3001, AZ-1518, and KMR-747. In some embodiments, an additional thin film may be deposited on the backside of the dies prior to deposition of the photoresist.

Referring to FIG. 8, the photoresist may be developed by exposure to one or more expanded laser beams incident at a preselected angle. After an exposure at one position, the photoresist may be rotated by 90 degrees or by 60 degrees and/or by 120 degrees and exposed again. Upon washing with a suitable developer [for example, AZ-400K], a square or triangular mask with a predetermined periodicity is formed. The periodicity may be controlled by changing the wavelength of the laser and the incidence angle during the exposure. In one specific embodiment, a He—Cd laser, operating at a wavelength of 325 nm, is used to expose the photoresist.

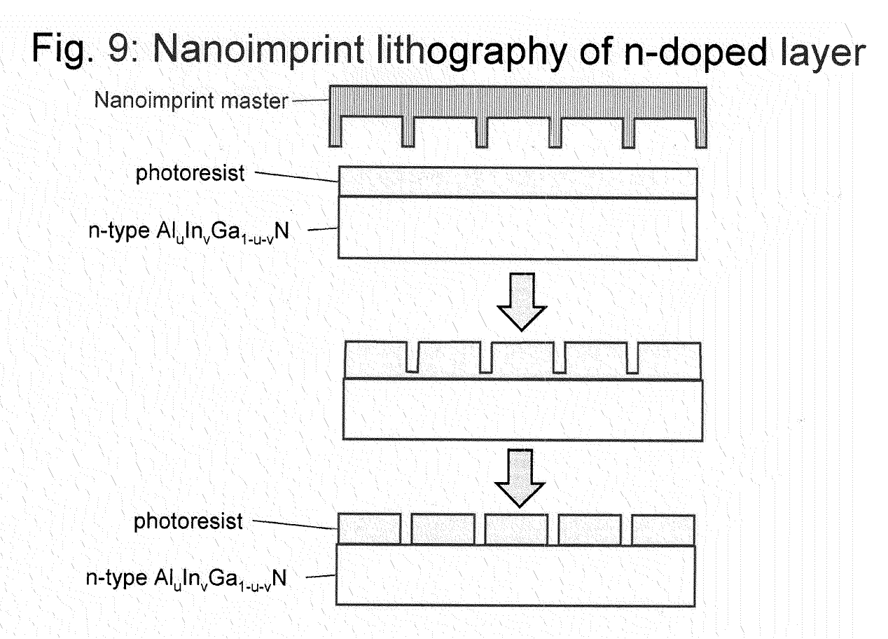

In another embodiment, the mask with a predetermined characteristic length scale is formed by nanoimprint lithography, as shown in FIG. 9. To fabricate a nanoimprint master, a photoresist may be applied to a silicon wafer with a 6-nm-thick SiO₂ coating. The photoresist may be exposed at least two incident angles, as described above, to form a patterned photoresist on the silicon wafer. In another embodiment, the photoresist for the nanoimprint master is patterned by electron-beam lithography instead of or in addition to patterning by holographic lithography. Two consecutive etching treatments, for example, by reactive ion etching, may transfer the pattern from the photoresist to the SiO₂ layer and then into the silicon wafer. The final depth of the pattern in the silicon wafer surface may be between about 100 nm and about 500 nm. Next, a photoresist layer may be deposited onto the flip-chipped GaN substrates. One example of a suitable photoresist for this process is Nanonex NXR-1010. The photoresist is then imprinted by the silicon master at a predetermined temperature and pressure. In one specific embodiment, the temperature is about 130 degrees Celsius and the pressure is about 300 pounds per square inch. The thin layer of polymer left in the bottom of hollows produced by the imprinting process may then be etched away by performing reactive ion etching with O₂.

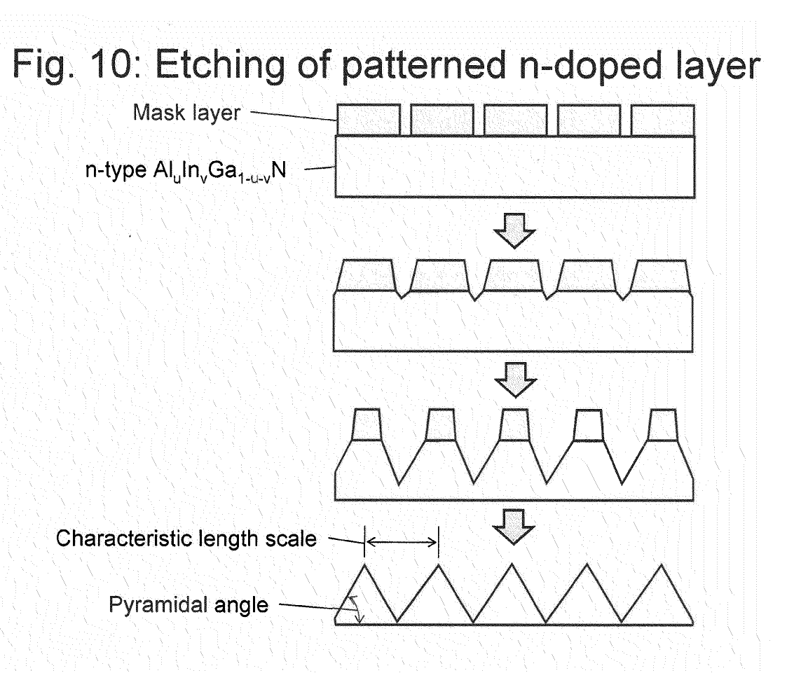

Referring to FIG. 10, pyramidal features may then be etched into at least half the exposed surface of the n-type layer. The etching conditions are selected so that the mask and, in particular, the edges of the mask, are etched at the same time as the n-type layer is being etched. The pyramidal angle, that is, the angle between the sides of the pyramids and the surface, may be controlled by preselecting the thickness of the mask layer, the width of the openings in the mask, and the relative erosion rates of the mask and of the n-type layer. As used herein, the term “pyramidal” is not restricted to perfect pyramids and also refers to structures that may be variously described as conical or tapered. In another specific embodiment, the etching process produces a textured structure on at least half of the exposed surface of the n-type layer, characterized by having a plurality of localized pyramidal angles of between about 10 degrees and about 90 degrees with respect to the surface region and a characteristic lateral length scale between about 10 nm and about 1000 nm.

In one specific embodiment, a SiOₓN_{y} layer is deposited on the backside of the n-type layer prior to deposition of the photoresist layer. The photoresist is patterned by either holographic lithography or nanoimprint lithography, as described above. The pattern is transferred from the photoresist to the SiOₓN_{y} by reactive ion etching, for example, using a mixture of CF₄ or CHF₃ with O₂.

The masked n-type layer is then reactive-ion-etched using a mixture of Cl₂ and SF₆, CF₄, or another F-containing species. The ratio of Cl₂ to SF₆ is adjusted to give the desired relative etch rates—etching of GaN is faster in Cl₂ than in SF₆, whereas the opposite is true for etching of SiOₓN_{y}—leading to a pyramidal angle between about 30 and about 90 degrees. The process is continued for a predetermined duration until formation of the pyramidal structures is complete.

In another set of embodiments, a pattern is formed in the photoresist using a stepper.

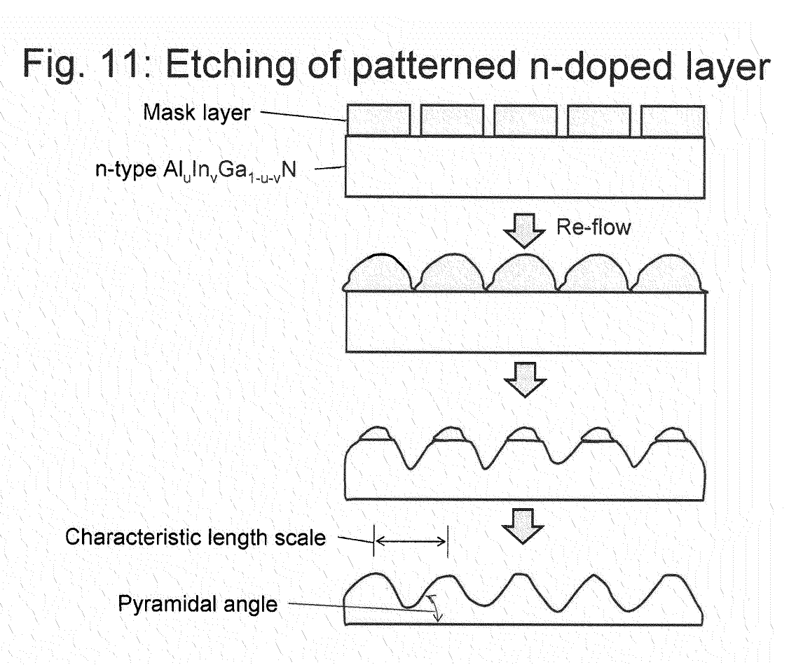

In another specific embodiment, illustrated in FIG. 11, the photoresist is re-flowed so as to provide a mask with a non-uniform cross section. Suitable examples of the photoresist include Nanonex NXR-1010, SPR 220-3.0, SPR 220-7.0, SPR 955CM-1.8, SPR 955CM-0.9, PMGI, SF-11, SF-13, SF-15, AZ 4330, AZ 4210, and AZ 4110. The photoresist is then heated to a temperature between about 100 degrees Celsius and about 250 degrees Celsius, for a duration between about one millisecond and about 10 minutes so as to cause a predetermined extent of re-flow. The re-flow causes the photoresist islands to become rounded, with a non-uniform cross section, and may also cause them to broaden slightly. The masked n-type layer is then dry etched to form a texture pattern, a microlens pattern, or the like. A greater degree of etching occurs near the perimeters of the re-flowed photoresist than in the center. The aspect ratio of the texture or microlens pattern, and the effective pyramidal angle, between 10 and 90 degrees, may be adjusted by varying the thickness of the photoresist layer, the diameter of the openings, the extent of re-flow, and the relative etch rates of the nitride semiconductor layer and the photoresist.

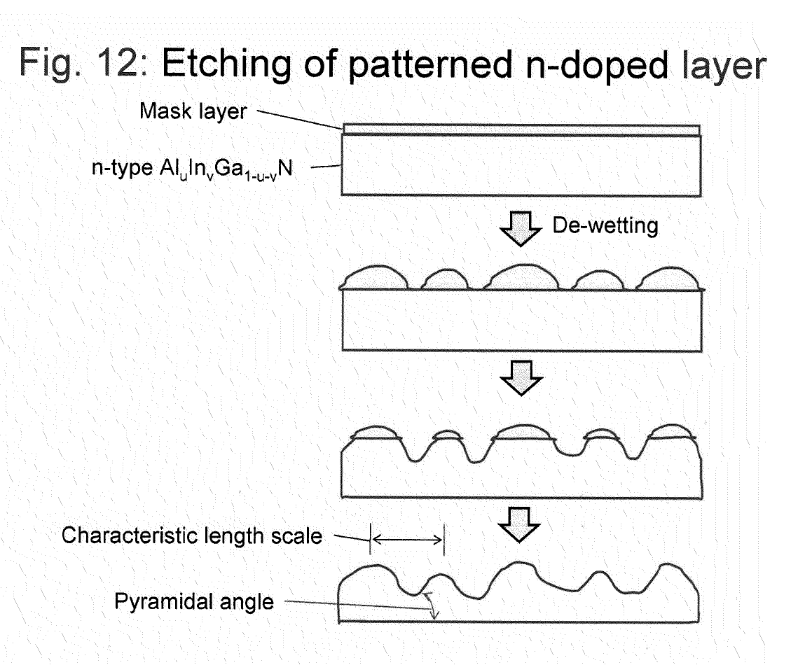

In another set of embodiments, the mask layer is deposited as a film and then caused to de-wet, generating openings. The mask layer may be deposited by sputtering, e-beam evaporation, thermal evaporation, or the like. The mask layer may comprise at least one of S, Ga, In, Zn, Al, Sn, Ag, Cu, Ni, Pb, Bi, Hg, or Cd. After deposition, the mask layer is heated, to a temperature between about 100 degrees Celsius and about 600 degrees Celsius, for a duration between about one millisecond and about 10 minutes, so as to cause de-wetting, as illustrated schematically in FIG. 12. The de-wetting process causes formation of openings in the mask layer and also causes the mask islands to become rounded, with a non-uniform cross section. The masked n-type layer is then dry etched to form a texture pattern, a microlens pattern, or the like. A greater degree of etching occurs near the perimeters of the de-wetted mask than in the center. The aspect ratio of the texture or microlens pattern, and the effective pyramidal angle, may be adjusted by varying the thickness of the mask layer, the de-wetting conditions, and the relative etch rates of the nitride semiconductor layer and the photoresist.

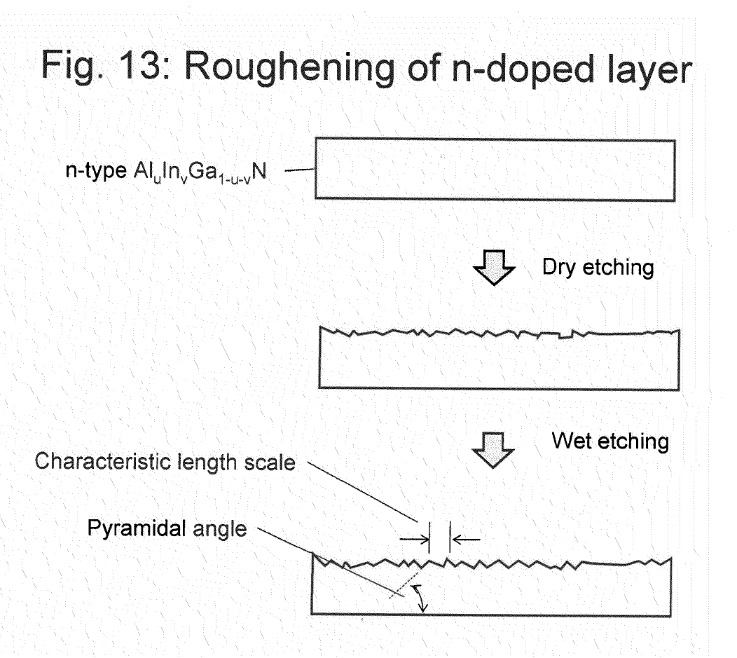

In yet another embodiment, a roughened or textured surface is formed by reactive ion etching under conditions where there is a strong physical component, such as a relatively high Ar pressure or a relatively high voltage, as illustrated schematically in FIG. 13. Some lattice damage may occur during this process, which may be removed by wet etching.

In still another embodiment, lattice damage is deliberately introduced into the exposed surface of the device, for example, by low energy ion bombardment. The damaged region is then removed by wet etching.

Some of these etch techniques may be combined. For example, in one specific embodiment, holographic lithography may be used for etch an array of holes or grooves, which are then formed into pyramidal structures by photoelectrochemical etching. In another embodiment, illumination during photoelectrochemical etching is provided by exposure to one or more expanded laser beams incident at a preselected angle. Interference between laser light waves in the semiconductor material give rise to a 1-dimensional or 2-dimensional grating of photogenerated carriers, causing photoelectrical chemical etching that is similarly modulated in one or two dimensions. The directionality of the periodically-modulated photoelectrochemical etching can be enhanced by the use of an electrical bias.

In some embodiments, the surface roughness of the pyramidal structures is greater than 50 nm, for example, as measured by atomic force microscopy.

The light extraction efficiency of the textured surface light emitting diode may be greater than 50%. In a preferred embodiment, the light extraction efficiency of the textured surface light emitting diode is greater than 75%. The light extraction efficiency may be defined as the external quantum efficiency divided by the internal quantum efficiency. The external quantum efficiency may be measured by methods that are well known in the art. Rigorous determination of the internal quantum efficiency may be more difficult. However, the internal quantum efficiency may be measured with sufficient accuracy as the ratio of the external quantum efficiency at room temperature to the external quantum efficiency at low temperature, for example, below 10 degrees Kelvin.

In some embodiments, at least one textured-surface light emitting diode is packaged along with at least one phosphor, as described in U.S. patent application 61/086,139, entitled “White light devices using non-polar or semipolar gallium containing materials and phosphors,” which is hereby incorporated by reference in its entirety. In other embodiments, at least one textured-surface light emitting diode is co-packaged along with at least one additional light emitting diode, as described in U.S. patent application 61/076,596, entitled “Copackaging configurations for nonpolar GaN and/or semipolar GaN LEDs,” which is hereby incorporated by reference in its entirety.

While the above is a full description of the specific embodiments, various modifications, alternative constructions and equivalents may be used. Therefore, the above description and illustrations should not be taken as limiting the scope of the present invention which is defined by the appended claims.

1. A light emitting diode comprising:
a semiconductor active layer comprising a gallium species and a nitrogen species, the semiconductor active layer being characterized by a peak emission wavelength;
a semiconductor n-type layer comprising a gallium species and a nitrogen species overlying the semiconductor active layer;
a semiconductor p-type layer comprising a gallium species and a nitrogen species overlying the semiconductor active layer;
an electrical contact coupled to one or more portions of the semiconductor n-type layer;
a reflective electrical contact coupled to at least one of the semiconductor p-type layer or the semiconductor n-type layer;
an active layer surface dislocation density below about 10⁵ cm⁻² characterizing the active layer;
an n-type layer surface dislocation density below about 10⁵ cm⁻² characterizing the n-type layer;
a p-type layer surface dislocation density below about 10⁵ cm⁻² characterizing the p-type layer; and
one or more pyramidal structures texturing at least half of a surface region of at least one of the n-type layer or p-type layer, the one or more pyramidal structures having a plurality of pyramidal angles of between about 10 degrees and about 90 degrees with respect to the surface region and the one or more pyramidal structures having a characteristic length scale between about 10 nm and about 1000 nm.

2. The light emitting diode of claim 1, wherein the active layer surface dislocation density is below 10⁴ cm⁻², the n-type layer surface dislocation density is below 10⁴ cm⁻², and the p-type layer surface dislocation density is below 10⁴ cm⁻²; and the one or more pyramidal structures texturing are provided overlying at least half of the surface region.

3. The light emitting diode of claim 2, wherein the active layer surface dislocation density is below 10³ cm⁻², the n-type layer surface dislocation density is below 10³ cm⁻², the p-type layer surface dislocation density is below 10³ cm⁻².

4. The light emitting diode of claim 3, wherein the active layer surface dislocation density is below 10² cm⁻², the n-type layer surface dislocation density is below 10² cm⁻², and the p-type layer surface dislocation density is below 10² cm⁻².

5. The light emitting diode of claim 1, wherein the characteristic length scale of the pyramidal structure is between about 120 nm and about 250 nm.

6. The light emitting diode of claim 1, wherein an active layer surface orientation of the active layer is within 5 degrees of {1 −1 0 0}, an n-type surface orientation of the n-type layer is within 5 degrees of {1 −1 0 0}, and a p-type surface orientation of the p-type layer is within 5 degrees of {1 −1 0 0}.

7. The light emitting diode of claim 1, wherein an active layer surface orientation of the active layer is within 5 degrees of {1 1 −2 0}, an n-type surface orientation of the n-type layer is within 5 degrees of {1 1 −2 0}, and a p-type surface orientation of the p-type layer is within 5 degrees of {1 1 −2 0}.

8. The light emitting diode of claim 1, wherein an active layer surface orientation of the active layer is within 5 degrees of {1 −1 0±1}, an n-type surface orientation of the n-type layer is within 5 degrees of {1 −1 0±1}, and a p-type surface orientation of the p-type layer is within 5 degrees of {1 −1 0±1}.

9. The light emitting diode of claim 1, wherein an active layer surface orientation of the active layer is within 5 degrees of {1 −1 0±2}, an n-type surface orientation of the n-type layer is within 5 degrees of {1 −1 0±2}, and a p-type surface orientation of the p-type layer is within 5 degrees of {1 −1 0±2}.

10. The light emitting diode of claim 1, wherein an active layer surface orientation of the active layer is within 5 degrees of {1 −1 0±3}, an n-type surface orientation of the n-type layer is within 5 degrees of {1 −1 0±3}, and a p-type surface orientation of the p-type layer is within 5 degrees of {1 −1 0±3}.

11. The light emitting diode of claim 1, wherein an active layer surface orientation of the active layer is within 5 degrees of {1 1 −2±2}, an n-type surface orientation of the n-type layer is within 5 degrees of {1 1 −2±2}, and a p-type surface orientation of the p-type layer is within 5 degrees of {1 1 −2±2}.

12. The light emitting diode of claim 1, wherein an active layer surface orientation of the active layer is within 5 degrees of {2 0 −2±1}, an n-type surface orientation of the n-type layer is within 5 degrees of {2 0 −2±1}, and a p-type surface orientation of the p-type layer is within 5 degrees of {2 0 −2±1}.

13. The light emitting diode of claim 1, wherein an active layer surface orientation of the active layer is within 5 degrees of (0 0 0 1), an n-type surface orientation of the n-type layer is within 5 degrees of (0 0 0 1), and a p-type surface orientation of the p-type layer is within 5 degrees of (0 0 0 1).

14. The light emitting diode of claim 1, wherein an active layer surface orientation of the active layer is within 5 degrees of (0 0 0 −1), an n-type surface orientation of the n-type layer is within 5 degrees of (0 0 0 −1), and a p-type surface orientation of the p-type layer is within 5 degrees of (0 0 0 −1).

15. (canceled)

16. (canceled)

17. (canceled)

18. (canceled)

19. (canceled)

20. (canceled)

21. (canceled)

22. A method of making a light emitting diode, the method comprising:
providing a high quality nitride crystal comprising a base nitride crystal and an overlying release layer, the high quality nitride crystal comprising a gallium species and a nitrogen species and having a surface dislocation density below 10⁵ cm⁻²;
forming an n-type semiconductor layer comprising a gallium species and nitrogen species overlying the release layer, a semiconductor active layer comprising a gallium species and a nitrogen species, the semiconductor active layer characterized by a peak light emission wavelength, and a p-type semiconductor layer comprising a gallium species and a nitrogen species overlying the high quality nitride crystal to form a sandwiched structure;
forming a reflective electrical contact overlying the p-type semiconductor layer;
separating the base nitride crystal from the sandwiched structure to expose a portion of the n-type layer; and
processing, using at least etching, at least half of the exposed portion of the n-type layer to form one or more pyramidal structures, with side angles of between about 10 degrees and about 90 degrees with respect to the exposed portion of the n-type layer and the one or more pyramidal structures having a characteristic length scale between about 10 nm and about 1000 nm.

23. The method of claim 22, wherein the wherein the high quality nitride crystal and the semiconductor layers comprise AlₓIn_{y}Ga_{1-x-y}N, where 0≦x, y, x+y≦1.

24. (canceled)

25. (canceled)

26. (canceled)

27. The method of claim 22, wherein the crystallographic orientation of the exposed n-type layer is (0 0 0 −1) and the one or more pyramidal structures is formed by photoelectrochemical etching.

28. (canceled)

29. The method of claim 28, wherein the crystallographic orientation of the exposed n-type layer is within 5 degrees of an orientation selected from {1 −1 0 0}, {1 −10 −1}, and {1 1 −2 −2}.

30. (canceled)

31. (canceled)

32. A light emitting diode comprising:
a semiconductor active layer comprising a gallium species and a nitrogen species, the semiconductor active layer being characterized by a peak emission wavelength;
a semiconductor n-type layer comprising a gallium species and a nitrogen species overlying the semiconductor active layer;
a semiconductor p-type layer comprising a gallium species and a nitrogen species overlying the semiconductor active layer;
an electrical contact coupled to one or more portions of the semiconductor n-type layer;
a reflective electrical contact coupled to at least one of the semiconductor p-type layer or the semiconductor n-type layer;
an active layer surface dislocation density below about 10⁵ cm⁻² characterizing the active layer;
an n-type layer surface dislocation density below about 10⁵ cm⁻² characterizing the n-type layer;
a p-type layer surface dislocation density below about 10⁵ cm⁻² characterizing the p-type layer; and
one or more textured structures provided overlying at least half of a surface region of at least one of the n-type layer or p-type layer, the one or more textured structures having a plurality of localized angles of between about 10 degrees and about 90 degrees with respect to the surface region and the one or more textured structures having a characteristic lateral length scale between about 10 nm and about 1000 nm.
